(19) United States
(12) Patent Application Publication
(10) Pub. No.: US 2024/0355892 A1
(43) Pub. Date: Oct. 24, 2024

(54) SEMICONDUCTOR DEVICE

(71) Applicant: ROHM CO., LTD., Kyoto (JP)

(72) Inventor: Yasunobu HAYASHI, Kyoto (JP)

(73) Assignee: ROHM CO., LTD., Kyoto (JP)

(21) Appl. No.: 18/763,081

(22) Filed: Jul. 3, 2024

Related U.S. Application Data
(63) Continuation of application No. PCT/JP2022/041005, filed on Nov. 2, 2022.

(30) Foreign Application Priority Data
Jan. 13, 2022 (JP) 2022-003936

(51) Int. Cl. H01L 29/423; H01L 21/28; H01L 29/40; H01L 29/51

(52) U.S. Cl. CPC H01L 29/4234; H01L 29/408; H01L 29/51; H01L 29/40117

(57) ABSTRACT

A semiconductor device includes a planar gate structure including a gate insulating film and a gate electrode, and a sidewall structure disposed adjacent to a lateral side of the planar gate structure. The sidewall structure includes a first insulating film and a second insulating film, and a charge storage film disposed between the first insulating film and the second insulating film. The first insulating film is adjacent to the planar gate structure. A ratio between a gate length L of the planar gate structure and a width WS of the sidewall structure is less than or equal to 300/75. Thereby, a semiconductor device having an improved data read and write reliability in a memory structure can be provided.

### TECHNICAL FIELD

The present disclosure relates to a semiconductor device, and more particularly to a semiconductor device including a non-volatile memory.

### BACKGROUND ART

For example, a semiconductor device including a non-volatile memory is disclosed in Japanese Patent Laying-Open No. 2005-064295 (PTL 1). In a memory included in the semiconductor device disclosed in PTL 1, a gate electrode is formed on a p well region, with a gate insulating film being interposed therebetween. On a lateral side of the gate electrode, a silicon oxide film, a silicon nitride film, and a silicon oxide film are sequentially stacked on a resistance change portion formed in a surface portion of the p well region. In this memory cell, write is performed by injecting hot electrons generated in the vicinity of a drain region into the silicon nitride film. Since this memory cell is used as an OTP-ROM (One Time Programmable Read Only Memory), an erase operation is not performed except for a conforming product check test.

### CITATION LIST

### Patent Literature

PTL 1: Japanese Patent Laying-Open No. 2005-064295

### BRIEF DESCRIPTION OF DRAWINGS

FIG. 1 is a plan view of a semiconductor device 1 in accordance with one embodiment of the present disclosure.

FIG. 2 is a cross sectional view taken along a line II-II shown in FIG. 1.

FIG. 3 is a cross sectional view taken along a line III-III shown in FIG. 1.

FIG. 4 is a circuit diagram for describing a write operation on a memory structure of the semiconductor device in accordance with one embodiment of the present disclosure.

FIG. 5 is a schematic cross sectional view for describing the write operation on the memory structure of the semiconductor device in accordance with one embodiment of the present disclosure.

FIG. 6 is a circuit diagram for describing a read operation on the memory structure of the semiconductor device in accordance with one embodiment of the present disclosure.

FIG. 7 is a schematic cross sectional view for describing the read operation on the memory structure of the semiconductor device in accordance with one embodiment of the present disclosure.

FIG. 8 is an enlarged view of a sidewall portion in FIG. 2.

FIG. 9 is a view for describing a threshold voltage of a memory element of the semiconductor device in the present embodiment.

FIG. 10 is a view for describing a threshold voltage of a memory element of a semiconductor device in a comparative study example.

FIG. 11 is a view showing the result of comparison of the threshold voltages in the present embodiment and the comparative study example.

FIG. 12 is a graph showing the correlation between the width of a sidewall and the threshold voltage in another experiment.

FIG. 13 is a flowchart showing a process for manufacturing the semiconductor device.

FIG. 14 is a first cross sectional view for describing the process for manufacturing the semiconductor device.

FIG. 15 is a second cross sectional view for describing the process for manufacturing the semiconductor device.

FIG. 16 is a third cross sectional view for describing the process for manufacturing the semiconductor device.

FIG. 17 is a fourth cross sectional view for describing the process for manufacturing the semiconductor device.

FIG. 18 is a schematic view of a semiconductor device having a memory element and an ordinary element mounted together.

FIG. 19 is a cross sectional view of MOS transistors formed in an OTP and an internal circuit, respectively.

### DESCRIPTION OF EMBODIMENTS

Hereinafter, an embodiment of the present disclosure will be described in detail with reference to the drawings. It should be noted that identical or corresponding parts in the drawings will be designated by the same reference numerals, and the description thereof will not be repeated.

### (Structure of Semiconductor Device)

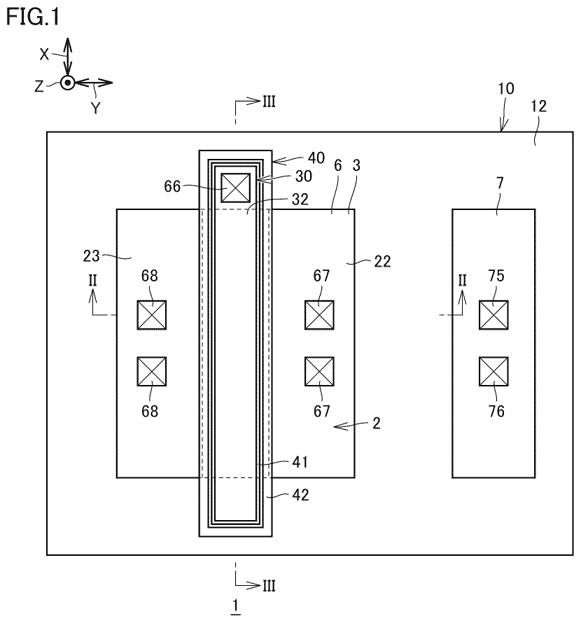

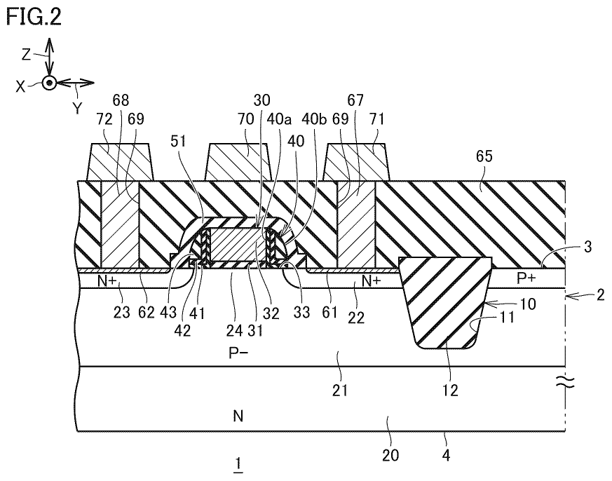

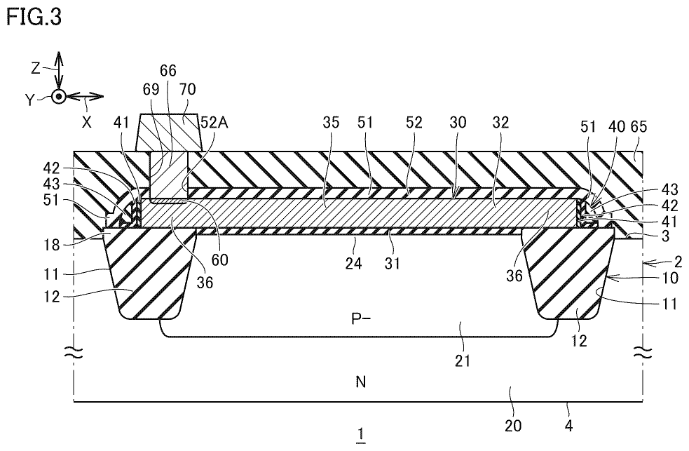

FIG. 1 is a plan view of a semiconductor device 1 in accordance with one embodiment of the present disclosure. FIG. 2 is a cross sectional view taken along a line II-II shown in FIG. 1. FIG. 3 is a cross sectional view taken along a line III-III shown in FIG. 1. It should be noted that an insulating spacer 43, a covering insulating film 51, an interlayer insulating film 65, and the like described later are omitted in FIG. 1 in order to clearly explain the configuration.

Semiconductor device 1 is a non-volatile memory that uses a MOSFET (Metal-Oxide-Semiconductor Field Effect Transistor). Semiconductor device 1 includes a semiconductor layer 2 made of an Si single crystal.

In the present embodiment, as shown in FIGS. 1 and 2, semiconductor layer 2 is formed in a rectangular parallelepiped shape. Semiconductor layer 2 has a first main surface 3 on one side, and a second main surface 4 on the other side. Semiconductor device 1 includes an epitaxial layer 20 having an n type (a first conductivity type) formed in semiconductor layer 2. Epitaxial layer 20 is formed over entire semiconductor layer 2.

Semiconductor device 1 is provided with a trench insulating structure 10 to define a device region in which the MOSFET is formed. Specifically, in semiconductor device 1 shown in FIG. 2, a trench 11 and an insulating buried object 12 are provided as trench insulating structure 10. Trench 11 is formed by digging down first main surface 3 toward second main surface 4. In plan view seen from a normal direction Z of first main surface 3 and second main surface 4 (hereinafter simply referred to as “in plan view”) as shown in FIG. 1, trench 11 is formed in a rectangular ring shape, and defines the device region in a rectangular shape. It should be noted that a direction in which one side of a device region 6 extends in plan view is referred to as a direction X. A direction orthogonal to both direction X and normal direction Z is referred to as a direction Y. Direction X and direction Y parallel to the main surfaces and normal direction Z of the main surfaces are shown in each of FIGS. 1 to 3.

In the present embodiment, trench 11 is formed in a tapered shape in which its opening width decreases toward a bottom wall. Trench 11 may have a taper angle of more than 90° and less than or equal to 125°. Preferably, the taper angle is more than 90° and less than or equal to 100°. The taper angle of trench 11 is an angle formed between an inner sidewall of trench 11 and first main surface 3 within semiconductor layer 2. Of course, trench 11 may be formed perpendicular to first main surface 3.

Trench 11 may have a depth of more than or equal to 0.1 μm and less than or equal to 1 μm. Trench 11 may have any width. Trench 11 may have a width of more than or equal to 0.1 μm and less than or equal to 10 μm. The width of trench 11 is defined by its width in a direction orthogonal to a direction in which trench 11 extends in plan view.

Insulating buried object 12 is buried in trench 11. Any insulator may constitute insulating buried object 12. Insulating buried object 12 may include at least one of silicon oxide (SiO₂) and silicon nitride (SiN). In the present embodiment, insulating buried object 12 is made of silicon oxide, for example. Insulating buried object 12 may have a portion protruding from semiconductor layer 2 (a protruding portion).

Semiconductor device 1 includes a well region 21 having a p type (a second conductivity type) formed in a surface portion of first main surface 3 in the device region. Well region 21 has a cross sectional structure shown in FIG. 2 that extends in direction X along first main surface 3. The p type impurity concentration of well region 21 is more than the n type impurity concentration of epitaxial layer 20. The p type impurity concentration of well region 21 is more than or equal to 10×10¹² cm⁻³ and less than or equal to 10×10¹⁶ cm⁻³, for example.

A bottom portion of well region 21 is electrically connected to epitaxial layer 20. In the present embodiment, well region 21 is formed deeper than trench 11, and partially covers the bottom wall of trench 11. Of course, unlike the present embodiment, well region 21 may be formed such that a boundary between well region 21 and epitaxial layer 20 is located at the same position as that of the bottom wall of trench 11.

Semiconductor device 1 includes a source region 22 (a first region) having the n type (the first conductivity type) formed in a surface portion of well region 21, and a drain region 23 (a second region) having the n type (the first conductivity type) formed in the surface portion of well region 21 to be spaced from source region 22. The n type impurity concentrations of source region 22 and drain region 23 are more than or equal to 10×10¹⁶ cm⁻³ and less than or equal to 10×10²⁰ cm⁻³, for example.

A channel region 24 of the MOSFET is formed between drain region 23 and source region 22. Channel region 24 forms a current path along direction Y between source region 22 and drain region 23.

It should be noted that, in the present specification, source region 22 and drain region 23 of semiconductor device 1 respectively indicate regions that serve as a source and a drain of the MOSFET when data is read from a memory element. During write, source region 22 and drain region 23 do not necessarily perform operations indicated by their names. It should be noted that, although the present embodiment describes that the first region is the source region and the second region is the drain region, the first region may be the drain region and the second region may be the source region.

Furthermore, in the case of an ordinary element, an LDD (Lightly Doped Drain) region having the n type (the first conductivity type) with an impurity concentration lower than those of source region 22 and drain region 23 (an N-LDD region) is additionally provided on a side including source region 22 and on a side including drain region 23. However, when used as a memory element, no N-LDD region is provided as shown in FIG. 5.

Semiconductor device 1 includes a planar gate structure 30 formed on first main surface 3 to face channel region 24. Planar gate structure 30 extends in direction X along first main surface 3. End portions of planar gate structure 30 in direction X reach insulating buried object 12 on the trench insulating structure. Unlike the present embodiment, the end portions of planar gate structure 30 in direction X may extend to the outside of the trench insulating structure. Planar gate structure 30 is located between source region 22 and drain region 23 in plan view.

Planar gate structure 30 includes a gate insulating film 31 formed on semiconductor layer 2, and a gate electrode 32 formed on gate insulating film 31. Gate insulating film 31 is made of an oxide of semiconductor layer 2. Specifically, gate insulating film 31 is made of an oxide formed in a film shape by oxidizing the surface portion of first main surface 3. That is, gate insulating film 31 is made of a silicon oxide film (an SiO₂ film) formed along first main surface 3. More specifically, gate insulating film 31 is made of a thermal oxide of semiconductor layer 2 formed in a film shape by thermally oxidizing the surface portion of first main surface 3 of semiconductor layer 2. That is, gate insulating film 31 is made of a silicon thermal oxide film (a thermal oxide film) formed along first main surface 3. Gate insulating film 31 may have a thickness of more than or equal to 7 nm and less than or equal to 13 nm.

Gate insulating film 31 extends in direction X along first main surface 3. Gate insulating film 31 has a first surface in contact with first main surface 3, and a second surface on a side opposite to semiconductor layer 2 with respect to first main surface 3. The first surface and the second surface are parallel to each other, and gate insulating film 31 may have a substantially constant thickness. Both end portions of gate insulating film 31 in direction X are connected with insulating buried object 12.

Gate electrode 32 is made of conductive polysilicon. Gate electrode 32 is formed on gate insulating film 31. A width of gate electrode 32 in direction Y (a gate length) may be more than or equal to 0.13 μm and less than or equal to 0.5 μm.

Referring to FIG. 3, gate electrode 32 traverses an opening end of trench 11 and reaches insulating buried object 12. Specifically, gate electrode 32 includes a main body portion 35 that faces first main surface 3 with gate insulating film 31 being sandwiched therebetween, and a drawn-out portion 36 that faces insulating buried object 12.

Main body portion 35 is formed on gate insulating film 31 along gate insulating film 31. Drawn-out portion 36 is drawn out from main body portion 35 onto a protruding portion 18 of insulating buried object 12.

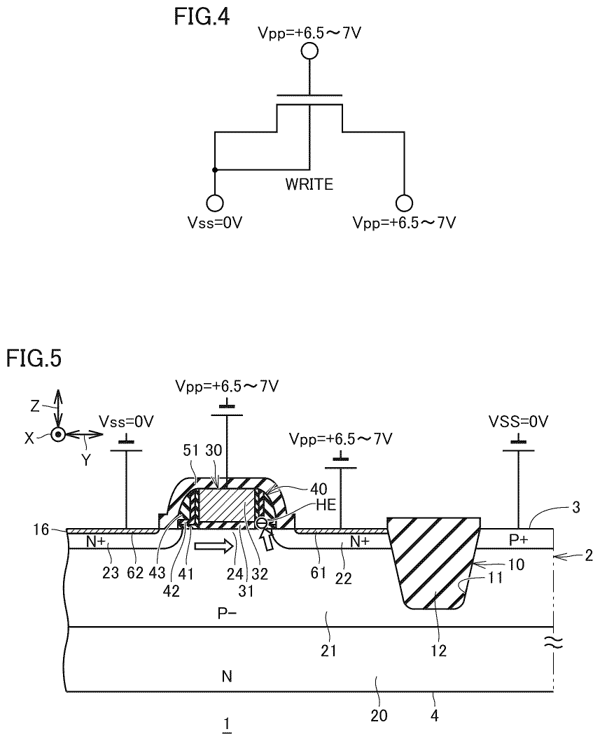

In semiconductor device 1, a sidewall structure 40 including a nitride film 42 of silicon nitride (SiN) is formed on a lateral side of planar gate structure 30. Sidewall structure 40 is disposed adjacent to the lateral side of planar gate structure 30 to cover a sidewall of gate electrode 32. Specifically, sidewall structure 40 covers a sidewall of main body portion 35 and also covers a sidewall of drawn-out portion 36 of gate electrode 32. In the present embodiment, data write, erase, and read can be performed utilizing sidewall structure 40 as described later with reference to FIGS. 4 to 7. Accordingly, sidewall structure 40 functions as a memory structure including a charge storage film in semiconductor device 1 which is a non-volatile memory. Since nitride film 42 functions as a charge storage film, it may hereinafter also be referred to as charge storage film 42.

Sidewall structure 40 has a rectangular ring shape surrounding planar gate structure 30 in plan view. Specifically, sidewall structure 40 is formed of a portion located between source region 22 and planar gate structure 30, a portion located between drain region 23 and planar gate structure 30, and a portion located on insulating buried object 12.

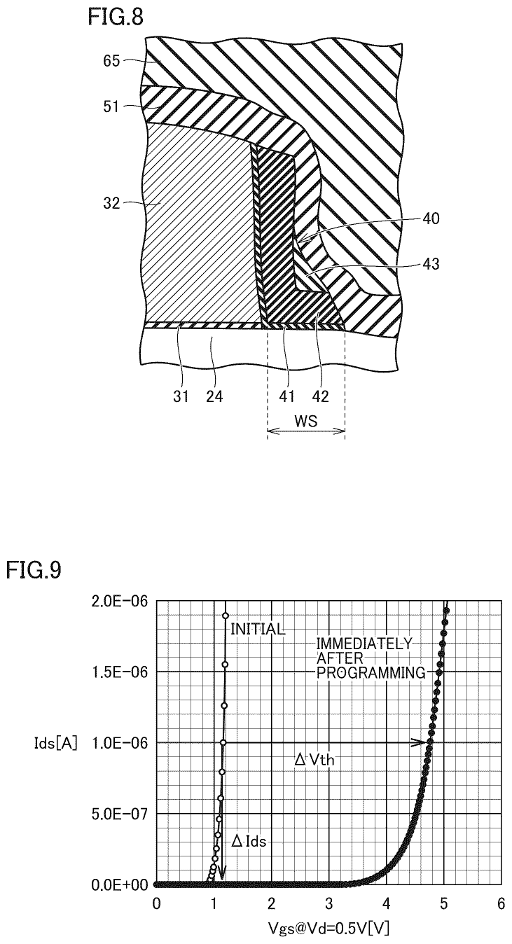

Referring to FIG. 2, sidewall structure 40 has an inner side surface 40a along a sidewall of planar gate structure 30, and an outer side surface 40b curved to protrude toward a side opposite to planar gate structure 30. Sidewall structure 40 is configured to include an insulating film 41, nitride film 42, and insulating spacer 43. Details of sidewall structure 40 will be described later with reference to FIG. 8.

Semiconductor device 1 further includes covering insulating film 51 that covers planar gate structure 30 and sidewall structure 40. Both end portions of covering insulating film 51 in direction Y are located from a lateral side of sidewall structure 40, on the side opposite to planar gate structure 30. Covering insulating film 51 extends in direction X, and both end portions of covering insulating film 51 in direction X reach insulating buried object 12 (see FIG. 3). Accordingly, covering insulating film 51 covers source region 22 and drain region 23, and further covers insulating buried object 12.

Specifically, covering insulating film 51 integrally has a portion covering gate electrode 32, a portion covering outer side surface 40b of sidewall structure 40, a portion covering source region 22 and drain region 23, and a portion covering the protruding portion of insulating buried object 12.

In covering insulating film 51, a through hole 52A is formed at a region that faces trench insulating structure 10 with gate electrode 32 being sandwiched therebetween (see FIG. 3).

Referring to FIGS. 2 and 3, semiconductor device 1 includes a gate silicide film 60, a source silicide film 61, and a drain silicide film 62. Referring to FIG. 3, gate silicide film 60 is formed at a portion of a surface of gate electrode 32 constituting a bottom portion of through hole 52A. Gate silicide film 60 is made of a polycide film formed integrally with gate electrode 32.

Referring to FIG. 2, source silicide film 61 and drain silicide film 62 are each made of a silicide film formed integrally with semiconductor layer 2. Source silicide film 61 is formed in a surface portion of source region 22, on a side opposite to sidewall structure 40 with respect to covering insulating film 51. Drain silicide film 62 is formed in a surface portion of drain region 23, on a side opposite to sidewall structure 40 with respect to covering insulating film 51.

Gate silicide film 60, source silicide film 61, and drain silicide film 62 may each contain at least one of TiSi, TiSi₂, NiSi, CoSi, CoSi₂, MoSi₂, and WSi₂.

Semiconductor device 1 includes interlayer insulating film 65 that covers first main surface 3. Interlayer insulating film 65 includes at least one of an oxide film (an SiO₂ film) and an nitride film (an SiN film). Interlayer insulating film 65 may have a single-layer structure composed of an oxide film or a nitride film. Interlayer insulating film 65 may have a multilayered structure in which one oxide film or a plurality of oxide films and one nitride film or a plurality of nitride films are stacked in any order. Interlayer insulating film 65 covers trench insulating structure 10, source region 22, drain region 23, planar gate structure 30, and sidewall structure 40, on first main surface 3.

Semiconductor device 1 includes a gate contact electrode 66, a source contact electrode 67, and a drain contact electrode 68 that penetrate through interlayer insulating film 65.

Gate contact electrode 66 is electrically connected to gate electrode 32, with gate silicide film 60 being interposed therebetween. Specifically, gate contact electrode 66 is electrically connected to gate electrode 32, and faces insulating buried object 12 with gate electrode 32 being sandwiched therebetween.

Unlike the present embodiment, when gate electrode 32 extends to an outer side of insulating buried object 12, gate contact electrode 66 may face semiconductor layer 2 on the outer side of insulating buried object 12.

Source contact electrode 67 is electrically connected to source region 22, with source silicide film 61 being interposed therebetween. Drain contact electrode 68 is electrically connected to drain region 23, with drain silicide film 62 being interposed therebetween.

Gate contact electrode 66, source contact electrode 67, and drain contact electrode 68 are buried in contact holes 69 formed in interlayer insulating film 65. Each contact electrode (gate contact electrode 66, source contact electrode 67, and drain contact electrode 68) is made of at least one of copper and tungsten.

A barrier electrode film may be provided between each contact electrode and an inner wall of contact hole 69. The barrier electrode film may have a single-layer structure composed of a Ti film or a TiN film. The barrier electrode film may have a multi-layered structure including a Ti film and a TiN film stacked in any order.

Semiconductor device 1 includes a gate wire 70, a source wire 71, and a drain wire 72 formed on interlayer insulating film 65. Gate wire 70 is electrically connected to gate contact electrode 66. Drain wire 72 is electrically connected to drain contact electrode 68. Source wire 71 is electrically connected to source contact electrode 67.

Each wire (gate wire 70, source wire 71, and drain wire 72) may include at least one of an Al film, an AlSiCu alloy film, an AlSi alloy film, and an AlCu alloy film. A barrier wire film may be provided between each wire and interlayer

insulating film 65. The barrier wire film may have a single-layer structure composed of a Ti film or a TiN film. The barrier wire film may have a multi-layered structure including a Ti film and a TiN film stacked in any order. The barrier wire film may also be provided on each wire.

Device region 6 shown in FIG. 1 is an N+ active region, and a P+ active region 7 is provided to the right thereof. Active region 7 is provided with electrodes 75 and 76.

### (Operations of Semiconductor Device)

Next, each operation (a write operation and a read operation) of semiconductor device 1 will be specifically described using the drawings. In both operations, a reference potential (0 V) is applied to a back gate region connected to well region 21.

FIG. 4 is a circuit diagram for describing the write operation on the memory structure of the semiconductor device in accordance with one embodiment of the present disclosure. FIG. 5 is a schematic cross sectional view for describing the write operation on the memory structure of the semiconductor device in accordance with one embodiment of the present disclosure. During write, a programming potential Vpp is applied to gate electrode 32 and source region 22, and a reference potential Vss is applied to drain region 23.

As shown in the schematic view of FIG. 5, the write operation of semiconductor device 1 is achieved by injecting electrons (hot electrons HE) flowing through source region 22 into nitride film 42 which is a charge storage film.

Specifically, during the write operation, a positive potential (for example, +6.5 to 7.5 V) is applied to gate electrode 32 and source region 22, and the reference potential (Vss=0 V) is applied to drain region 23. Thus, by applying a high voltage to between a source and a drain, hot carriers are generated and attracted to the positive potential of a gate, and a charge is trapped in the charge storage film of the sidewall. The write time is 0.1 ms to 100 ms, for example.

The gate potential and the source potential in the write operation are not limited to Vpp=+6.5 to 7.5V, and may be any potential selected from a range of more than or equal to 3 V and less than or equal to 8 V, for example. It should be noted that, the larger the amount of potential (absolute value) is, the faster the write operation of semiconductor device 1 is.

Due to a negative charge of the electrons injected into nitride film 42 which is a charge storage film by the write operation, a portion of a channel in channel region 24 disappears, and a current is less likely to flow between source region 22 and drain region 23. That is, due to the negative charge of the electrons injected into nitride film 42, a gate threshold voltage Vth increases.

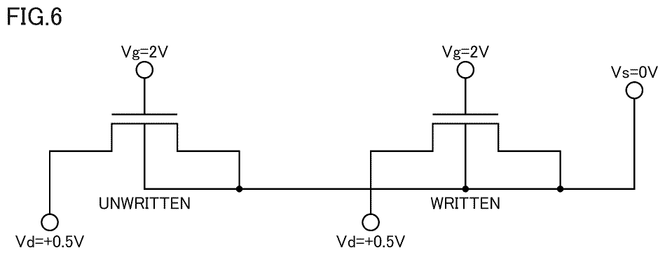

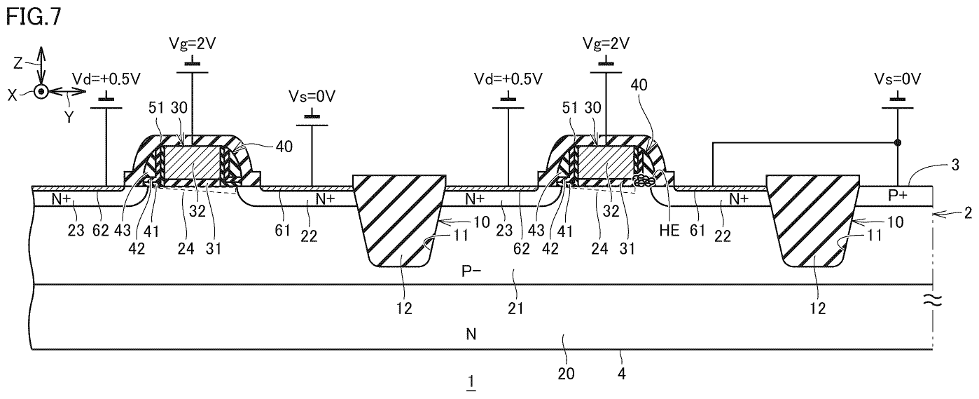

Next, the read operation of semiconductor device 1 will be described. FIG. 6 is a circuit diagram for describing the read operation on the memory structure of the semiconductor device in accordance with one embodiment of the present disclosure. FIG. 7 is a schematic cross sectional view for describing the read operation on the memory structure of the semiconductor device in accordance with one embodiment of the present disclosure.

In a written transistor (on the right side in FIG. 7), the charge injected into the charge storage film (nitride film 42) of the sidewall impedes an electric field generated by a gate potential Vg from reaching channel region 24, and thereby the channel is interrupted. Thus, no current flows through the written transistor (on the right side in FIG. 7) even when gate potential Vg is set to 2 V and a drain-source voltage Vgs is set to 0.5 V.

In contrast, in an unwritten transistor (on the left side in FIG. 7), when gate potential Vg is set to 2 V, a channel is formed and the transistor is turned on. Thus, a current flows even when drain-source voltage Vgs is set to 0.5 V.

Accordingly, during the read operation, it is possible to determine whether or not data is written in the memory structure based on the presence or absence of a drain-source current Ids, with a potential being applied to gate electrode 32.

Specifically, in both of the written transistor and the unwritten transistor, in the read operation, a positive potential is applied to gate electrode 32 (for example, Vg=2 V), a positive potential (for example, +0.5 V) is applied to drain region 23, and the reference potential is applied to source region 22 (Vs=0 V).

In written semiconductor device 1, as shown on the right side in FIG. 7, the channel in channel region 24 is interrupted due to the negative charge of the electrons injected into nitride film 42, and drain-source current Ids does not flow. In contrast, in unwritten semiconductor device 1, as shown on the left side in FIG. 7, no electrons are injected into nitride film 42, and thus a channel is formed in channel region 24 and drain-source current Ids flows.

### (Details of Sidewall Structure and Influence of Width WS on Threshold Voltage)

FIG. 8 is an enlarged view of a sidewall portion in FIG. 2. The dimension of the sidewall in Y direction in FIG. 2 is referred to as a width WS of the sidewall.

Sidewall structure 40 includes insulating film 41 formed on channel region 24, nitride film 42 that faces channel region 24 with insulating film 41 being sandwiched therebetween, and insulating spacer 43 formed on nitride film 42. Nitride film 42 is formed on channel region 24 and on insulating film 41 formed on the lateral side of planar gate structure 30, and functions as a charge storage film in the memory structure.

Insulating film 41 is made of an oxide of semiconductor layer 2 and gate electrode 32. Specifically, insulating film 41 is made of an oxide formed in a film shape by oxidizing a surface portion of semiconductor layer 2 and the sidewall of gate electrode 32. Insulating film 41 is made of a silicon oxide film (an SiO₂ film) formed along first main surface 3 and a side surface of gate electrode 32. More specifically, insulating film 41 is made of a thermal oxide formed in a film shape by thermally oxidizing the surface portion of semiconductor layer 2 and the sidewall of gate electrode 32. That is, insulating film 41 is made of a silicon thermal oxide film formed along first main surface 3 and the side surface of gate electrode 32.

Since insulating film 41 is made of an oxide of semiconductor layer 2 and gate electrode 32, it is not formed on insulating buried object 12 (see FIG. 3).

Insulating film 41 may have a thickness of more than or equal to 5 nm and less than or equal to 10 nm. Preferably, insulating film 41 is thinner than gate insulating film 31.

Insulating film 41 includes a portion extending along first main surface 3 of semiconductor layer 2, and a portion extending along the sidewall of planar gate structure 30. Insulating film 41 may be formed in an L shape in cross sectional view, with these portions being coupled orthogonal to each other.

Insulating film 41 is formed on first main surface 3, and is adjacent to gate insulating film 31. A surface of insulating film 41 on a first main surface 3 side is formed to be flush with a surface of gate insulating film 31 on the first main surface 3 side. It should be noted that the surface of insulating film 41 on the first main surface 3 side may be located closer to a second main surface 4 (see FIG. 2) side than the surface of gate insulating film 31 on the first main surface 3 side.

Nitride film 42, which is a charge storage film, is made of an insulator different from insulating film 41, and is made of a silicon nitride film (an SiN film), for example. Nitride film 42 is formed along insulating film 41. Nitride film 42 may have a thickness of more than or equal to 10 nm and less than or equal to 50 nm. It should be noted that, although it is described that the charge storage film is nitride film 42, the charge storage film may be any film that can store a charge, and is not limited to a nitride film.

Nitride film 42 has a rectangular ring shape surrounding planar gate structure 30 in plan view (see FIG. 1). That is, nitride film 42 extends in direction X, and both end portions of nitride film 42 in direction X are located on insulating buried object 12 (see FIG. 3).

Nitride film 42 includes a portion extending along a surface direction of first main surface 3, and a portion extending along a direction of the sidewall of planar gate structure 30. Nitride film 42 may be formed in an L shape in cross sectional view, with these portions being coupled orthogonal to each other.

Source region 22 and drain region 23 are formed in a self-aligned manner with respect to sidewall structure 40. Accordingly, a boundary between source region 22 and channel region 24 substantially matches a boundary between outer side surface 40b of sidewall structure 40 and first main surface 3, in plan view. Similarly, a boundary between drain region 23 and channel region 24 also substantially matches a boundary between outer side surface 40b of sidewall structure 40 and first main surface 3, when seen from Z direction shown in FIG. 2.

In a strict sense, the boundary between source region 22 and channel region 24 is located slightly closer to planar gate structure 30 than the boundary between outer side surface 40b of sidewall structure 40 and first main surface 3. Similarly, the boundary between drain region 23 and channel region 24 is also located slightly closer to planar gate structure 30 than the boundary between outer side surface 40b of sidewall structure 40 and first main surface 3.

Nitride film 42 has a depressed portion formed of the portion extending along the surface direction of first main surface 3 and the portion extending along the direction of the sidewall of planar gate structure 30. Insulating spacer 43 is disposed adjacent to nitride film 42 within the depressed portion. Insulating spacer 43 is made of a silicon oxide, for example. Insulating spacer 43 faces insulating film 41 with nitride film 42 being sandwiched therebetween.

As shown in FIG. 8, width WS of the sidewall is a dimension of the charge storage film (nitride film 42) on P well region 21 under the gate. When width WS is large, the area in which a charge can be stored during write increases, and thus the threshold voltage increases. For example, width WS is set to 30 nm to 100 nm.

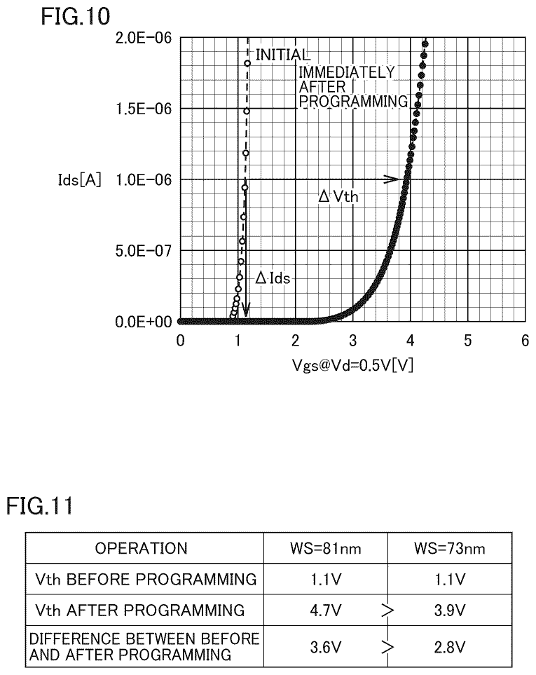

In the following, a difference in threshold voltage when width WS of the sidewall is changed will be described. FIG. 9 is a view for describing a threshold voltage of a memory element of the semiconductor device in the present embodiment. FIG. 10 is a view for describing a threshold voltage of a memory element of a semiconductor device in a comparative study example. Width WS of the sidewall is 81 nm in the present embodiment, and is 73 nm in the comparative example. Write conditions common to FIGS. 9 and 10 are Vpp=+6.8 V, Vss=0 V, and a write time Tw=10 ms. In each of FIGS. 9 and 10, a graph indicated by white circles shows Vgs-Ids characteristics in an initial (unwritten) state, and a graph indicated by black circles shows Vgs-Ids characteristics immediately after programming (after write). By write, the threshold voltage increases by ΔVth.

FIG. 11 is a view showing the result of comparison of the threshold voltages in the present embodiment and the comparative study example. It should be noted that threshold voltage Vth is set to a gate voltage Vg required to pass a current of 1 μA between the source and the drain. FIG. 11 is prepared by reading threshold voltages Vth at which Ids=1 μA/μm (a current flowing through a transistor with a gate width of 1 μm) flows, from the graphs in FIG. 9 (the present embodiment: WS=81 nm) and FIG. 10 (the comparative example: WS=73 nm), and comparing them.

First, threshold voltage Vth before programming was 1.1 V in both cases, so there is no difference between the present embodiment and the comparative example.

Next, threshold voltage Vth after programming was 4.7 V in the present embodiment, indicating a greater increase when compared with 3.9 V in the comparative example.

Thus, difference ΔVth between the threshold voltages before and after programming was 3.6 V in the present embodiment, and was 2.8 V in the comparative example.

Therefore, since the memory element in the present embodiment has a greater amount of increase in threshold voltage by write, when compared with that in the comparative example, it can be said that the memory element has a noise immunity, and that erroneous read and erroneous erase are less likely to occur.

FIG. 12 is a graph showing the correlation between the width of the sidewall and the threshold voltage in another experiment. In FIG. 12, write conditions are Vpp=+6.8 V, Vss=0 V, and Tw=10 ms, and read conditions are Vd=0.5 V and Id=1 μA/μm.

FIG. 12 shows an average value of threshold voltages Vth of each 80 samples having sidewall width WS of 66 nm, 73 nm, 78 nm, 81 nm, or 92 nm. As shown in FIG. 12, sidewall width WS and threshold voltage Vth have a linearly increasing relation.

Therefore, at least in a range where width WS of the sidewall is 66 to 92 nm, the larger width WS of the sidewall is, the greater the amount of increase in threshold voltage during write is. Therefore, as a memory element, the memory element with WS=81 nm in the present embodiment is more preferable to the memory element with WS=73 nm in the comparative example. Similarly, also concerning the memory elements with WS=78 nm and 92 nm, it can be said that, as memory elements, they are more preferable to the memory element in the comparative example. It can be seen from FIG. 12 that, when the planar gate structure has a gate length L of 0.4 μm, it is preferable that the sidewall structure has width WS of more than or equal to 75 nm. Furthermore, width WS is more preferably more than or equal to 78, and further preferably more than or equal to 81. In addition, preferably, a ratio R between gate length L of the planar gate structure and width WS of the sidewall structure is less than or equal to 300/75. Furthermore, ratio R is more preferably less than or equal to 300/78, and further preferably less than or equal to 300/81.

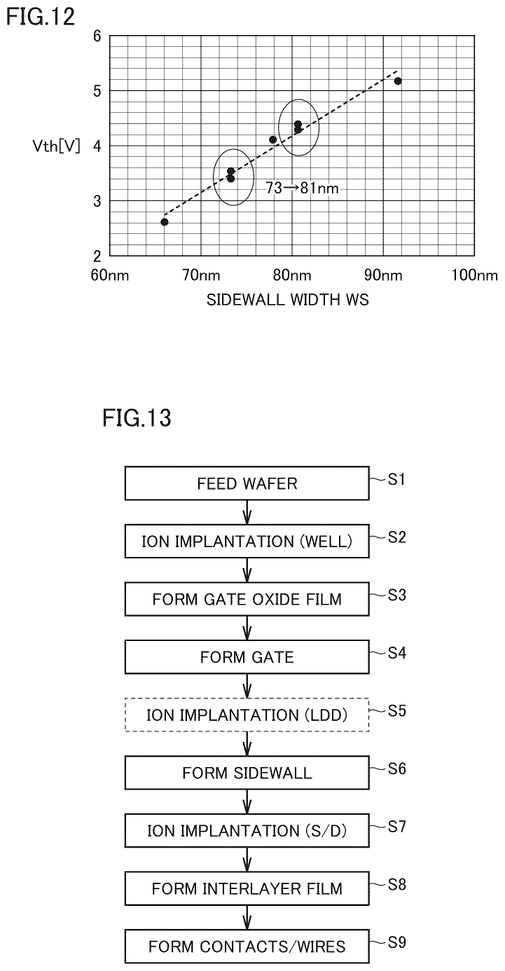

FIG. 13 is a flowchart showing a process for manufacturing the semiconductor device. First, in step S1, a wafer (a substrate having semiconductor layer 2) is fed into a manufacturing line. Although not shown, after formation of epitaxial layer 20, formation of a trench isolation structure is performed.

Thereafter, in step S2, ion implantation is performed on a well portion to form P well region 21. It should be noted that a well region having the N type may also be formed, for example when a CMOS circuit is mounted together.

Then, in step S3, a gate oxide film is formed. Gate insulating film 31 is formed by oxidizing a surface portion of a wafer main surface in a film shape by a thermal oxidation treatment method. Gate insulating film 31 has a thickness T of more than or equal to 7 nm and less than or equal to 13 nm, for example.

Then, in step S4, the gate electrode is formed. First, a conductive film to serve as gate electrode 32 is formed on the wafer main surface to cover gate insulating film 31 and insulating buried object 12. In the present embodiment, gate electrode 32 is made of conductive polysilicon. Gate electrode 32 is formed by a CVD method, for example.

Then, a resist mask having a pattern is formed by an exposure step, and an unnecessary portion of gate electrode 32 is removed by an etching method via the resist mask. The etching method may be any of a dry etching method (for example, an RIE method) and a wet etching method. Wet etching may be performed by supplying HF (hydrofluoric acid), for example. Thereby, gate electrode 32 is formed. Thereafter, the resist mask is removed.

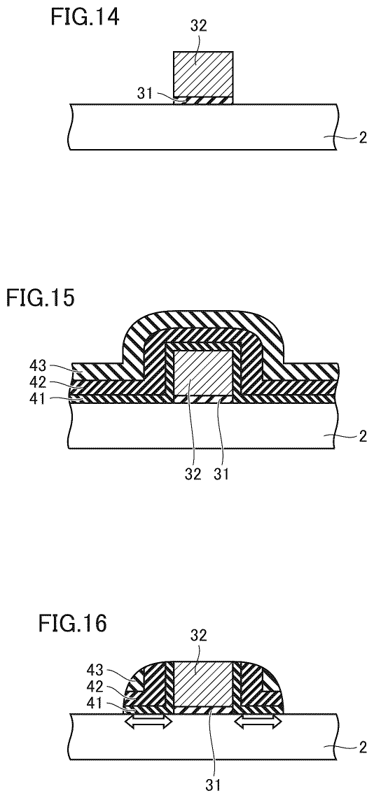

FIG. 14 is a first cross sectional view for describing the process for manufacturing the semiconductor device. FIG. 14 shows a state where step S4 is finished, that is, a cross sectional structure of semiconductor device 1 at a stage where the gate electrode is formed, and shows a state where gate insulating film 31 and gate electrode 32 are formed in semiconductor layer 2 having a well formed therein.

After step S4, LDD ion implantation in step S5 is performed in a region of an internal circuit in which an ordinary transistor other than a memory element is disposed (described later in FIG. 18), whereas the LDD ion implantation is not required in an OTP region in which a memory element is formed. In the following, the LDD ion implantation selectively performed on a region in which the internal circuit is formed will be described.

Although not shown in FIG. 2 that shows a memory element, an LDD region is an n type diffusion layer adjacent to source region 22 and the drain region. The LDD region has an impurity concentration lower than those of source region 22 and the drain region. Since the LDD ion implantation is performed after forming the gate and before forming the sidewall, the LDD region is formed immediately under the sidewall, rather than under gate electrode 32.

Then, in step S6, formation of the sidewall is performed.

FIG. 15 is a second cross sectional view for describing the process for manufacturing the semiconductor device. FIG. 16 is a third cross sectional view for describing the process for manufacturing the semiconductor device. The formation of the sidewall will be described using FIGS. 15 and 16. First, as shown in FIG. 15, insulating film 41, nitride film 42, and an insulating film to serve as insulating spacer 43 are sequentially formed.

Insulating film 41 is formed in a film shape by oxidizing the surface portion of semiconductor layer 2 and the sidewall of gate electrode 32. That is, insulating film 41 is a silicon thermal oxide film formed along first main surface 3 and the side surface of gate electrode 32. Insulating film 41 may have a thickness of more than or equal to 5 nm and less than or equal to 10 nm. Preferably, insulating film 41 is thinner than gate insulating film 31.

Then, nitride film 42 is formed. Nitride film 42, which is a charge storage film, is made of an insulator different from insulating film 41, and is made of a silicon nitride film (an SiN film), for example. Nitride film 42 is formed along insulating film 41. Nitride film 42 may have a thickness of more than or equal to 10 nm and less than or equal to 50 nm.

Furthermore, an oxide film to serve as insulating spacer 43 is formed by the CVD method using TEOS (tetraethyl orthosilicate: Si(OC₂H₅)₄).

Both nitride film 42 and the oxide film to serve as insulating spacer 43 are deposited by an isotropic film formation method (for example, the CVD method). When formation of the three films is finished as shown in FIG. 15, then, the sidewall structure is formed by anisotropic etching. As the etching method on this occasion, the dry etching method (for example, the RIE method) is used, for example.

On this occasion, as a technique of increasing width WS of the sidewall, it is conceivable to (1) increase the thickness of the oxide film/nitride film, (2) shorten an etching time, and the like.

It can be confirmed that increasing the film thickness of any of nitride film 42 and the oxide film to serve as insulating spacer 43 has an effect of improving electrical characteristics. It should be noted that width WS of the sidewall can also be increased by merely adjusting the etching time.

It should be noted that, if isotropic etching is performed as etching for the three insulating films, width WS of the sidewall is decreased, which is disadvantageous as a memory element.

Conversely, in an ordinary transistor without having a memory function, it can have a higher current capability and is advantageous also in terms of operation speed when width WS of the sidewall is narrower. A technique of mounting a transistor having a memory function together with an ordinary transistor may be adopted by forming the transistor having a memory function separately from the ordinary transistor, through such a technique as covering only a memory element with a resist after etching is finished to secure width WS of the sidewall, and then additionally performing isotropic etching slightly, for example.

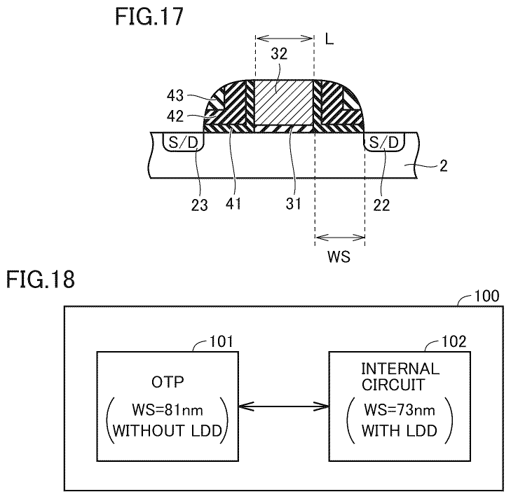

FIG. 17 is a fourth cross sectional view for describing the process for manufacturing the semiconductor device. After the sidewall structure is formed as shown in FIG. 16, source region 22 and drain region 23 are formed in a self-aligned manner with respect to gate electrode 32 and the sidewall by ion implantation, as shown in FIG. 17.

Thereafter, although not shown, formation of an interlayer film and formation of contacts/wires are performed, and thereby semiconductor device 1 is completed.

FIG. 18 is a schematic view of a semiconductor device having a memory element and an ordinary element mounted together.

In recent years, development of LSIs (Large Scale Integrations) with a memory function has been promoted. For example, development of memories directly using a conventional CMOS (Complementary Metal-Oxide-Semiconductor) process or BCDMOS (Bipolar CMOS Double-diffused MOS) process has been promoted. The memory element in the present embodiment is applicable to such an LSI.

A semiconductor device 100 includes an OTP-ROM (hereinafter an OTP) 101 including a memory element, and an internal circuit 102 including circuits such as a microcomputer and a logic. Internal circuit 102 can use information stored in the memory element of the OTP as appropriate, and write information in the memory element based on the result of computation.

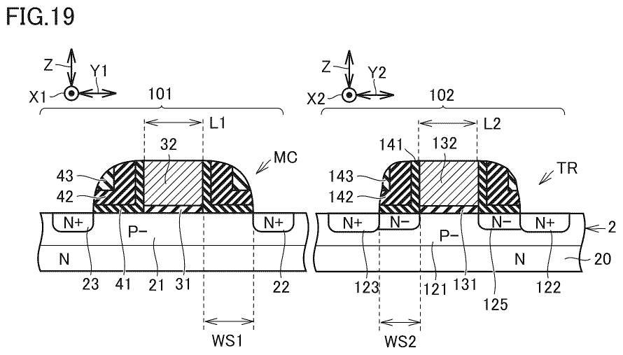

FIG. 19 is a cross sectional view of MOS transistors formed in the OTP and the internal circuit, respectively.

OTP 101 includes a MOS transistor in which a width WS1 of a sidewall is 81 nm, as a memory element, and internal circuit 102 includes a MOS transistor in which a width WS2 of a sidewall is 73 nm, as a circuit element.

Preferably, the LDD ion implantation shown in step S5 in FIG. 13 is not performed in a region in which OTP 101 is formed, whereas the LDD ion implantation shown in step S5 is performed in a region in which internal circuit 102 is formed. As a result, an LDD region 125 is formed in the MOS transistor of internal circuit 102.

With such a configuration, a memory element having a noise immunity can be implemented even in an LSI with a memory function.

It should be noted that, in FIGS. 19, X1 and X2 may be the same direction or different directions. Similarly, Y1 and Y2 may be the same direction or different directions.

### CONCLUSION

In the following, the present embodiment will be summarized with reference to the drawings again.

The present disclosure relates to semiconductor device 1. As shown in FIGS. 1 and 2, semiconductor device 1 includes: semiconductor layer 2 having a main surface; well region 21 formed in a surface portion of the main surface of semiconductor layer 2; and first region 22 and second region 23 formed in a surface portion of well region 21 to be spaced from each other in a first direction (Y direction). First region 22 and second region 23 have a first conductivity type (n type). Well region 21 has a second conductivity type (p type). Semiconductor device 1 further includes: a planar gate structure including gate insulating film 31 and gate electrode 32 formed to be stacked on the main surface of semiconductor layer 2 in a second direction (Z direction) so as to face channel region 24 between first region 22 and second region 23; and a memory structure disposed adjacent to a lateral side in the first direction (Y direction) of the planar gate structure disposed on a side of first region 22. The memory structure includes first insulating film 41 and a second insulating film 43, and charge storage film 42 disposed between first insulating film 41 and second insulating film 43. First insulating film 41 is adjacent to the planar gate structure (31, 32) in the first direction (Y direction). Charge storage film 42 is formed as sidewall structure 40 covering lateral sides in the first direction (Y direction) of gate insulating film 31 and gate electrode 32. As shown in FIG. 17, a ratio between gate length L of the planar gate structure along the first direction (Y direction) and width WS of the sidewall structure along the first direction (Y direction) is less than or equal to 300/75.

Preferably, a thickness of first insulating film 41 is thinner than a thickness of second insulating film 43. It should be noted that the thickness of second insulating film 43 is the maximum part of its thickness stacked on charge storage film 42 shown in a cross section in FIG. 8, for example.

Preferably, charge storage film 42 is made of SiN, and each of first insulating film 41 and second insulating film 43 is made of SiO₂.

More preferably, first insulating film 41 is a thermal oxide film of polysilicon, and second insulating film 43 is a TEOS oxide film.

Preferably, when the gate length is less than or equal to 0.3 μm, width WS of the sidewall structure is more than or equal to 75 nm.

Preferably, the first conductivity type is an n type, and the second conductivity type is a p type.

Preferably, the memory structure is configured to inject hot electrons into the charge storage film during a write operation.

The present disclosure relates to semiconductor device 100 in another aspect. Semiconductor device 100 shown in FIGS. 18 and 19 includes: semiconductor layer 2 having a main surface; OTP 101 including a memory element MC formed in the semiconductor layer; and internal circuit 102 including a transistor TR formed in semiconductor layer 2. Memory element MC includes first region 22 and second region 23 formed in a surface portion of a first well region 21 formed in a surface portion of the main surface of semiconductor layer 2, to be spaced from each other in a first direction (Y1 direction). First region 22 and second region 23 have a first conductivity type (n type), and first well region 21 has a second conductivity type (p type). Memory element MC further includes: a first planar gate structure including a first gate insulating film 31 and a first gate electrode 32 formed to be stacked on the main surface of the semiconductor layer in a second direction (Z direction) intersecting the main surface so as to face a channel region between first region 22 and second region 23; and a memory structure disposed adjacent to a lateral side in the first direction (Y1 direction) of the first planar gate structure disposed on a side of first region 22. The memory structure includes first insulating film 41 and second insulating film 43, and charge storage film 42 disposed between first insulating film 41 and second insulating film 43. First insulating film 41 is adjacent to the first planar gate structure in the first direction (Y1 direction). Charge storage film 42 is formed as a first sidewall structure covering lateral sides in the first direction (Y1 direction) of first gate insulating film 31 and first gate electrode 32.

Transistor TR of internal circuit 102 includes: a third region 122 and a fourth region 123 formed in a surface portion of a second well region 121 formed in the surface portion of the main surface of semiconductor layer 2 so as to be spaced from each other in a third direction (Y2 direction), third region 122 and fourth region 123 having the first conductivity type (n type), second well region 121 having the second conductivity type (p type); a second planar gate structure including a second gate insulating film 131 and a second gate electrode 132 formed to be stacked on the main surface of semiconductor layer 2 in the second direction (Z direction) so as to face a channel region between third region 122 and fourth region 123, the second direction intersecting the main surface; and a second sidewall structure disposed adjacent to a lateral side in the third direction (Y2 direction) of the second planar gate structure disposed on a side of third region 122. The second sidewall structure includes a third insulating film 141 and a fourth insulating film 143, and a fifth insulating film 142 disposed between third insulating film 141 and fourth insulating film 143. Third insulating film 141 is adjacent to the second planar gate structure in the third direction (Y2 direction).

A first width WS1 of the first sidewall structure along the first direction (Y1 direction) is larger than a second width WS2 of the second sidewall structure along the third direction (Y2 direction).

Preferably, a ratio L1/WS1 between a first gate length L1 of the first planar gate structure along the first direction (Y1 direction) and width WS1 of the first sidewall structure along the first direction (Y1 direction) is less than or equal to 300/75, and a ratio L2/WS2 between a second gate length L2 of the second planar gate structure along the third direction (Y2 direction) and width WS2 of the second sidewall structure along the third direction (Y2 direction) is more than 300/75.

It should be understood that the embodiment disclosed herein is illustrative and non-restrictive in every respect. The scope of the present invention is defined by the scope of the claims, rather than the description of the embodiment described above, and is intended to include any modifications within the scope and meaning equivalent to the scope of the claims.

### REFERENCE SIGNS LIST

1, 100: semiconductor device; 2: semiconductor layer; 3: first main surface; 4: second main surface; 6: device region; 7: active region; 10: trench insulating structure; 11: trench; 12: insulating buried object; 18: protruding portion; 20: epitaxial layer; 21: well region; 22: source region; 23: drain region; 24: channel region; 25: LDD region; 30: planar gate structure; 31: gate insulating film; 32: gate electrode; 35: main body portion; 36: drawn-out portion; 40: sidewall structure; 40a: inner side surface; 40b: outer side surface; 41: insulating film; 42: charge storage film; 43: insulating spacer; 51: covering insulating film; 52A: through hole; 60: gate silicide film; 61: source silicide film; 62: drain silicide film; 65: interlayer insulating film; 66: gate contact electrode; 67: source contact electrode; 68: drain contact electrode; 69: contact hole; 70: gate wire; 71: source wire; 72: drain wire; 75, 76: electrode; 101: OTP; 102: internal circuit; 121: second well region; 122: third region; 123: fourth region; 131: second gate insulating film; 132: second gate electrode; 141: third insulating film; 142: fifth insulating film; 143: fourth insulating film; MC: memory element; TR: transistor.

1. A semiconductor device comprising:
a semiconductor layer having a main surface;
a well region formed in a surface portion of the main surface of the semiconductor layer;
a first region and a second region formed in a surface portion of the well region to be spaced from each other in a first direction, the first region and the second region having a first conductivity type, the well region having a second conductivity type;
a planar gate structure including a gate insulating film and a gate electrode formed to be stacked on the main surface of the semiconductor layer in a second direction so as to face a channel region between the first region and the second region; and
a sidewall structure disposed adjacent to a lateral side in the first direction of the planar gate structure disposed on a side of the first region, wherein
the sidewall structure includes
a first insulating film and a second insulating film, and
a charge storage film disposed between the first insulating film and the second insulating film,
the first insulating film is adjacent to the planar gate structure in the first direction, and
a ratio between a gate length of the planar gate structure along the first direction and a width of the sidewall structure along the first direction is less than or equal to 300/75.

2. The semiconductor device according to claim 1, wherein a thickness of the first insulating film is thinner than a thickness of the second insulating film.

3. The semiconductor device according to claim 1, wherein the charge storage film is made of SiN, and each of the first insulating film and the second insulating film is made of SiO₂.

4. The semiconductor device according to claim 3, wherein the first insulating film is a thermal oxide film of polysilicon, and the second insulating film is a TEOS oxide film.

5. The semiconductor device according to claim 1, wherein, when the gate length is less than or equal to 0.3 μm, the width of the sidewall structure is more than or equal to 75 nm.

6. The semiconductor device according to claim 1, wherein the first conductivity type is an n type, and the second conductivity type is a p type.

7. The semiconductor device according to claim 1, wherein the semiconductor device is configured to inject hot electrons into the charge storage film during a write operation.

8. A semiconductor device comprising:
a semiconductor layer having a main surface;
a memory element formed in the semiconductor layer; and
a transistor formed in the semiconductor layer, wherein
the memory element includes
a first region and a second region formed in a surface portion of a first well region formed in a surface portion of the main surface of the semiconductor layer, to be spaced from each other in a first direction, the first region and the second region having a first conductivity type, the first well region having a second conductivity type,
a first planar gate structure including a first gate insulating film and a first gate electrode formed to be stacked on the main surface of the semiconductor layer in a second direction intersecting the main surface so as to face a channel region between the first region and the second region, and
a first sidewall structure disposed adjacent to a lateral side in the first direction of the first planar gate structure disposed on a side of the first region,
the first sidewall structure includes
a first insulating film and a second insulating film, and
a charge storage film disposed between the first insulating film and the second insulating film,
the first insulating film is adjacent to the first planar gate structure in the first direction,
the transistor includes
a third region and a fourth region formed in a surface portion of a second well region formed in the surface portion of the main surface of the semiconductor layer so as to be spaced from each other in a third direction, the third region and the fourth region having the first conductivity type, the second well region having the second conductivity type,
a second planar gate structure including a second gate insulating film and a second gate electrode formed to be stacked on the main surface of the semiconductor layer in the second direction so as to face a channel region between the third region and the fourth region, the second direction intersecting the main surface, and
a second sidewall structure disposed adjacent to a lateral side in the third direction of the second planar gate structure disposed on a side of the third region,
the second sidewall structure includes
a third insulating film and a fourth insulating film, and
a fifth insulating film disposed between the third insulating film and the fourth insulating film,
the third insulating film is adjacent to the second planar gate structure in the third direction, and
a ratio between a first gate length of the first planar gate structure along the first direction and a first width of the first sidewall structure along the first direction is less than or equal to 300/75.

9. The semiconductor device according to claim 8, wherein the first width of the first sidewall structure is larger than a second width of the second sidewall structure along the third direction.

10. The semiconductor device according to claim 9, wherein a ratio between a second gate length of the second planar gate structure along the third direction and the second width of the second sidewall structure is more than 300/75.
